(19) United States
(12) Patent Application Publication
(10) Pub. No.: US 2026/0186880 A1
(43) Pub. Date: Jul. 2, 2026

(54) Parallel Memory Repair Memory Repair Controller

(71) Applicant: Google LLC, Mountain View, CA (US)

(72) Inventors: Mayank Parasrampuria, Bangalore (IN); Kartik Rao, Bangalore (IN)

(21) Appl. No.: 19/005,345

(22) Filed: Dec. 30, 2024

(51) Int. Cl. G11C 29/44

(52) U.S. Cl. CPC G06F 11/073; G11C 29/4401

(57) ABSTRACT

The disclosed technology includes a technique and architecture in which a repair controller and memory blocks or subsystems communicate using a parallel data transfer protocol. For instance, a repair controller includes a memory repair controller that is coupled to a one time programming (OTP) controller or fuse box and to the respective receive units/modules in individual memory blocks. The repair controller includes a transmit unit/module and functions as a BISR controller.

### BACKGROUND

Memory repair is a process for correcting defects or errors in memory blocks of integrated circuitry. The defects are typically identified through memory testing. It is important to detect such defects, correct them if possible or if correction is not possible, avoid using the errored memory location. In modern day computing devices, memory repair procedures are typically invoked during boot up or, in some cases, when an application is instantiated. For instance, a smart phone typically employs system on a chip (SoC) technology. SoCs typically use a memory repair system referred to as built-in self-repair (BISR) to replace faulty memory elements with backup memory elements. As part of memory repair, a repair signature is calculated. On boot up or instantiation of an application, the data representing the repair signature is transferred to the memory and faulty memory areas are diverted to spare rows and columns. The time taken to perform boot-up impacts user experience.

### SUMMARY

The disclosed technology includes a memory repair control system that includes a memory repair controller that enables memory repair on multiple memory blocks so as to speed up the memory repair process and improve user experience.

The disclosed technology may take the form of a system, process or method, or an apparatus (e.g., a memory repair controller). For example, an aspect of the disclosed technology includes a memory repair system, comprising a memory repair controller having a transmit unit and a one time programming memory controller; a plurality of memory blocks, each memory block having a receive unit and a power manager; and one or more parallel data buses communicatively coupled between the transmit unit of the memory repair controller and at least one receive unit of the plurality of memory blocks and communicatively coupled between the transmit unit of the memory repair controller and at least one power manager of the plurality of memory blocks.

In accordance with this aspect of the disclosed technology, the at least one power manager requests memory repair data from the transmit unit of the memory repair controller. Further, the at least one power manager may request memory repair data using a request that includes a receive unit identifier and a repair identifier associated with the at least one receive unit. Further still, the transmit unit transmits repair data to the at least one receive unit using the receive unit identifier. The repair data may also include a repair signature for the at least one receive unit. In addition, the receive unit identifier identifies a specific memory within a memory block associated with the at least one power manager.

Further in accordance with this aspect of the disclosed technology, a first data bus of the plurality of parallel data buses is used from transmitting data from the transmit unit of the memory repair controller to the at least one receive unit of the plurality. Further still, a second data bus of the plurality of parallel data buses is used for transmitting data between the transmit unit and the at least one power manager of the plurality of memory blocks. In addition, the first data bus may be different than the second data bus.

Further in accordance with this aspect of the disclosed technology, the one or more parallel data buses include a parallel repair bus for communicating repair data from the transmit unit of the memory repair controller to a receive unit of each of the plurality of memory blocks.

Further in accordance with this aspect of the disclosed technology, the one or more parallel data buses includes a parallel request bus for communicating repair requests between a power manager of each of the plurality of memory blocks and the transmit unit.

Further in accordance with this aspect of the disclosed technology, each memory block of the plurality of memory blocks is associated with a power domain of a system on a chip.

Further in accordance with this aspect of the disclosed technology, the one or more parallel data buses comprise one or more parallel broadcast buses.

Further in accordance with this aspect of the disclosed technology, the transmit unit comprises a request sequencer receiving memory repair requests from at least one power manager.

In another example, the disclosed technology may be a method for performing memory repair comprising receiving, at a memory repair controller, a request for repair data associated with a memory block; receiving, at the memory repair controller, memory repair data associated with the memory block; broadcasting, by the memory repair controller, the memory repair data on a parallel broadcast data bus coupled to the memory block and at least one other memory block; receiving at the memory block the repair data; and processing one or more memories associated with the memory block based on the memory repair data. In accordance with this aspect of the disclosed technology, broadcasting the memory repair data comprises broadcasting the memory data and receive unit identifier associated with a receive unit of the memory block. Further in accordance with this aspect of the disclosed technology, the method comprises sending, by a power manager of the memory block, the request for repair data on a repair data bus. In addition, the repair data is contained in a repair word and processing comprises determining a receive unit identifier associated with the repair word and decoding a repair signature from the repair word when the receive unit identifier is determined to match an identifier associated with the memory block.

In another example, the disclosed technology may take the form of a memory repair controller, comprising a load request handler having a request sequencer and configured to receive memory repair requests from one or more power managers; a translator coupled to a one time programmable memory and configured to receive repair data stored in the one time programmable memory; a logic for comparing receiver identifiers associated with the one or more power managers to the received memory repair requests to determine whether a given part of the memory repair data received by the translator corresponds to a memory repair request; and an output that broadcasts a message to one or more receive units when the logic indicates that there is a match between a receiver identifier and a memory repair request of the received memory requests. In accordance with this aspect of the disclosed technology, the request sequencer accumulates received memory requests for a predetermined time period. Further, the memory repair controller may cause the one time programmable memory to provide its contents to the translator after the predetermined time period expires. In addition, the logic may receive memory repair requests from the request sequencer.

### BRIEF DESCRIPTION OF THE DRAWINGS

FIG. 1 illustrates an example system in accordance with an aspect of the disclosed technology.

FIG. 2 illustrates an example message format in accordance with an aspect of the disclosed technology.

FIG. 3 illustrates an example of a block diagram and process flow in accordance with an aspect of the disclosed technology.

FIG. 4 illustrates an example of a block diagram and process flow in accordance with an aspect of the disclosed technology.

FIG. 5 illustrates an example of a block diagram and process flow in accordance with an aspect of the disclosed technology.

FIG. 6 is a flow chart illustrating a process flow in accordance with an aspect of the disclosed technology.

### DETAILED DESCRIPTION

The disclosed technology includes a technique and architecture in which a repair controller and memory blocks or subsystems communicate using a parallel data transfer protocol. For instance, a repair controller includes a memory repair controller that is coupled to a one time programming (OTP) controller or fuse box and to the respective receive units/modules in individual memory blocks. The repair controller includes a transmit unit/module and functions as a BISR controller. However, the transmit unit uses receive identifiers (IDs) to broadcast memory repair content on a data bus that connects the memory repair controller with all the memory blocks. Thus, only the memory block associated with the receive ID processes the memory content broadcasted on the bus. This provides a mechanism that allows for processing memory repairs for different memory blocks in parallel.

In addition to the receive ID, the data broadcasted by the repair controller includes a repair ID that identifies a specific memory within the memory block and a repair signature associated with the repair ID which indicates what to repair.

Further, each memory block includes a power domain manager that is configured to request repair data for the memory block it belongs to. The request indicates to the repair controller that the power domain is up and therefore requires its repair data, e.g., its repair signature. The request also identifies the power domain and memory block by including the receive ID in the request. When the transmit module receives the request, it acquires the repair data for that power domain manager from the OTP controller or module and broadcasts it on the bus. The receive unit in the memory block associated with the receive ID included in the request and associated with the requesting power domain manager receives the repair data and processes it to effect memory repair for that memory block. While other memory blocks or power domains may receive the repair data information, they will not process it as it does not include their respective receive ID and does not belong to them. As such, a parallel data transfer bus protocol for memory repair is provided.

In addition, the transmit module operates to read all the data for each request so that all the OTP data is processed and based on requesting receive ID the data for those repair controllers is broadcasted on the network in response to each request. This is effected by the manner in which the OTP contents are maintained. The OTP contents are stored so that a receive ID is associated with a repair ID and repair signature. Thus, even while contents of the OTP is broadcasted in response to each request, a given memory block will only process the data intended for it.

Memory repair techniques typically rely on a serial repair interface that allows sending repair data to each memory as part of a serial stream generated by a single engine (e.g., BISR controller). In effect, such memory repair controllers sends repair data to a particular memory block serially, e.g., reads repair data for a particular memory locations and sends the data for that memory location before reading and sending data for another memory location, such that each memory block is repaired as part of a series of repair transactions (e.g., read and repair one block before moving to another). This approach adds unnecessary delay to the boot up time (boot latency) or to the time it takes an application to become useable (wake up latency) as only one memory block in effect is allowed to use the repair process at any given time. The disclosed technology allows multiple repair processes to function at the same time. Furthermore, ordering of storage of data in the OTP is not required—data can be stored randomly because of the use of receive ID. There is also no need to store data in the OTP for all memory blocks, instead only storage of data for memory blocks that have been identified as having faulty memory blocks may be stored—reducing the required size of the OTP and avoiding the need to allocate OTP memory for every memory block. The disclosed technology can also avoid using compression to store OTP data and thus avoids delay due to decompression. It also allows for less than 100 microseconds latency and latency can be made dependent on the size of the OTP. The disclosed technology further allows for flexibility to determine how to allocate OTP memory, e.g., only store repair data for blocks above a given failure rate or don't store repair data for blocks without known failures. In addition, it allows adding new power managers and associated blocks—modular design.

The disclosed technology also allows communications of the repair controller and memory blocks to be asynchronous. Moreover, power can be saved by powering off inactive receive units. In addition, run time is governed only by the time it takes to read the OTP and multiple pipelines can exist for a given memory block.

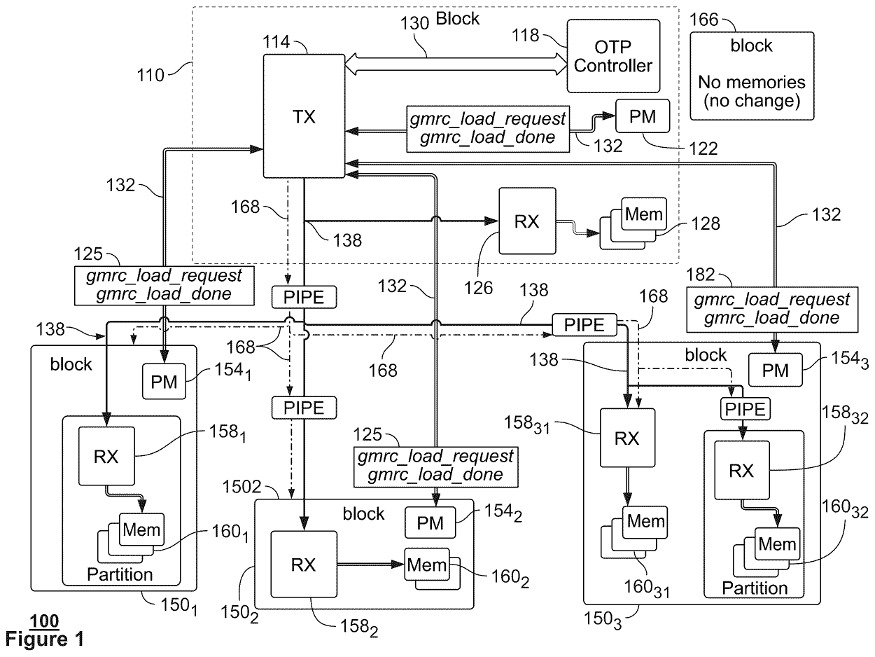

FIG. 1 illustratively depicts a system 100 for parallel memory repair in accordance with an aspect of the disclosed technology. The system 100 includes a memory repair controller 110 coupled to a plurality of memory blocks or power domains 150. While FIG. 1 shows three memory blocks 150, an actual implementation may include more than three memory blocks or one memory block. The system 100 may comprise part of a SoC, such as that used in a smartphone, tablet or various other modern day user devices.

Memory controller 110 includes transmit module (TX) 114, OTP controller or fuse box 118, power manager (PM) 122, receiver module (RX) 126 and one or more memory blocks or partitions 128. The transmit module 114 manages and controls how memory repair data is stored, understood and transmitted within the system 100. The transmit module may take the form of a hardware device and/or one or more software programs. For example, it may take the form of an ASIC that is designed to carry out the functions necessary for managing and controlling memory repair communications and data flow in accordance with the aspects of the disclosed technology. Alternatively, it may also comprise a CPU that is programmed using instructions to carry out the functions of managing the memory repair communications and data flow. It may also alternatively comprise the instructions themselves for managing the memory repair process (e.g., communications and data flow).

The transmit module 114 is coupled to the OTP controller 118 via a first data bus 130. The transmit module 114 uses the data bus 130 to request and fetch repair information via OTP controller 118. The OTP controller 118 includes a dedicated controller (not shown) and OTP memory (not shown). The OTP memory is typically considered a fuse box. In an aspect of the disclosed technology, the OTP controller 118 may be considered a fuse box, e.g., from the perspective of the transmit module 114. The dedicated controller of OTP controller 118 controls access (e.g., read and write access) to the OTP memory. The OTP memory holds the repair information for the memories used in a device that the includes the system 100. The repair information includes corrupted memories location information and associated repair signatures.

The transmit module 114 is also coupled to PM 122 via a second data bus 132. Data bus 132 comprises a control/command data bus. It is used by the transmit module 114 to receive and respond to requests from PM 122 in effecting memory repair. PM 122 controls the power domain associated with the transmit module 110. For example, PM 122 signals the transmit module 114 when memory repair information is required for memory controller 110, e.g., at boot up and/or in response to requests from other power managers or power domain blocks (e.g., blocks 150). As shown in FIG. 1, the transmit module 114 may use two messages 125 in communicating with PM 122: “request” and “done.” For instance, the PM 122 may issue a “request” to transmit module 122 indicating that it requires repair data for its corresponding power domain, i.e., memory controller 110. When the request is satisfied, transmit module 122 may provide a “done” response to PM 122. This informs the PM 122 that the repair data for the memory 128 for memory controller 110 has been loaded and will be broadcasted for use in repairing the memory associated with the memory controller 110 power domain.

In that regard, transmit module 114 is also coupled to a receiver module 126 via a third data bus 138. Data bus 138 is used to transport repair data between the transmit module 114 and the receiver modules in system 110, including receiver module 126. Data bus 138 may be considered a repair data bus or repair network. The repair data generally includes the identification of the memory blocks that require repair and the repair signature for the memory block (e.g., the backup memory to use to avoid using an errored memory block). For instance, in response to a memory load request from PM 122, the transmit module fetches the memory repair data for memory repair controller 110 and broadcasts such memory repair on third or repair memory data bus 138. Receiver module 126 recognizes that the repair data on the data bus 138 is intended for receiver module 126. Receiver module 126 therefore accesses the repair data so that it can be used to repair errored memory blocks within memory 128. Once memory repair of such errored memory blocks is effected, transmit module 114 may then be used by other parts of the system, e.g., memory blocks 150, to effect memory repair.

As shown in FIG. 1, system 100 also includes memory blocks or power domains 150. Each memory block 150 is associated with a power domain. A power domain comprises one or more modules or functionality that may need to be powered up or made active at a given instant in time. Examples of power domains include a camera module, phone module, a microphone module, a communication module, etc. In some instances, a power domain may comprise the camera module and the microphone module. More specifically, where the system 110 is part of an SoC for a user device, the camera module, speaker and microphone module may be considered a power domain when the user seeks to establish a video call with another user given that all three of these functionalities are need for a video call. As another example, if the user seeks to take a still photograph, then the camera module is only module that needs to be powered on to enable the user device to take the photograph and therefore the camera module would comprise a power domain. Each power domain or memory block 150 is associated with memory elements that are needed to support the relevant module(s). Accordingly, when a power domain is invoked, the memory repair procedure is invoked so that the relevant module(s) can have available required and uncorrupted memory to perform the requested functionality (e.g., take a photograph).

Each memory block 150 includes a PM 154, one or more receiver (RXs) modules or units 158 and one or more memory elements 160. Each PM 154 is coupled to command/control data bus 132. Each PM 154 is configured to transmit a request to transmit module 114 over command/control data bus 132 to obtain memory repair data in order to have the power domain associated with each PM 154 become activate and perform a given function.

Each receiver module 158 is coupled to repair data bus 138, which as previously discussed is also coupled to transmit module 114. The repair data bus 138 facilitates communication of repair data in parallel between transmit module 114 and each memory block 150 via respective receiver modules 158 to form a repair network. As is further discussed below, each receiver module 158 (including receiver module 126) is provided with a receiver identifier that uniquely identifies it on the repair network. As such, the transmit module can communicate repair data messages to individual receiver modules 158, and hence to individual blocks or power domains 150. Each receiver module 158 is also coupled to one or more respective memory elements 160 within each memory block 150. The repair data provided over data bus 138 is used to perform memory repair associated with memory elements 160. In a case where a block or subsystem includes no memory elements, such as block 166, then there is no need to equip that block with a RX module.

As also shown in FIG. 1, the system 100 includes a clock 168. The clock 168 is generated by transmit module 114. transmit module 114 synchronizes the repair data on data bus 138 with clock 168. On the other hand, the flow control with a given PM is asynchronous. The repair data is pipelined at multiple stages along with the clock 168 as illustrated by the PIPE blocks. Because the RX units operate independently there is no need to skew the repair data across the different blocks/memory subsystems 150 as the repair data can reach different subsystems at different times. Additionally, power savings are possible as the transmit module 114 does not have to be always on.

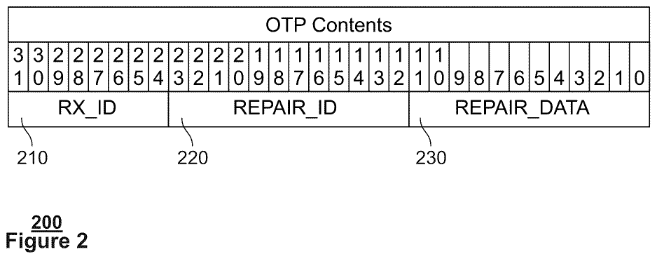

In operation, the system 100 is capable of having memory repair occur in parallel among the memory blocks or power domains 150. At a high level, operations take place as follows. Transmit module 114 fetches repair data from OTP controller/fuse box 118 and broadcasts the data it fetches over repair data bus or network 138 to receivers 126 and 158. The data is broadcasted in the form of a message 200 having a data format as shown in FIG. 2. As shown in FIG. 2, the message 200 includes a RX_ID field 210, Repair_ID field 220 and a Repair_Data field 230. A unique RX_ID is allocated to each power domain, block or memory subsystem 110 and 150. As each receiver 126/158 is provided with a unique RX_ID, a receiver 126/158 will only detect and process repair data or words intended for it. Other blocks/memory subsystems that the repair data message is not intended for will ignore it having not recognized the RX_ID as its own. When a RX unit 126/158 detects a message intended for it, it determines the Repair_ID and Repair_Data from the message. The Repair_ID identifies the specific memory element(s) within block or memory subsystem 110 and 150 that is to be repaired. The Repair_Data comprises the repair signature. The Repair_ID and Repair_Data will typically be stored in the OTP memory of OTP controller 118. With the Repair_ID and Repair_Data, the block/memory subsystem 110/150 may effect memory repair. Once the transmit module broadcasts a repair message on repair data bus 138 for a first block/memory subsystem, it may then broadcast another repair message intended for a second and different block/memory subsystem. Thus, the first and second blocks/memory repair subsystems may effect memory repair in parallel. That is, there is no need for the memory repair process for a given power domain, block or memory subsystem to be completed before providing memory repair data to another power domain, block or memory subsystem.

As a more specific example, PM 154₃ may issue a request for memory repair to transmit module 114 using for example a <request> message 182₁. The request serves as an indication to the transmit module 114 that its block or power domain 150₃ is up and requires repair data. The request identifies the block/subsystem 154₃ as the requesting block/subsystem via the RX_ID. Upon receiving the request, transmit module 114 queries OTP controller to read and provide the contents of the OTP memory of fuse box. OTP controller 118 accesses its OTP memory and returns to transmit module 114 the contents of the OTP memory. Once transmit module 114 receives the repair data, it issues a <done> message 182₂ to PM 154₃ and broadcasts the repair data in the form of a message 200 on repair data bus 138. Although all the blocks/memory subsystems will receive the message, RX 158₃₁ and/or 158₃₂ will decode the message based on detection of the RX_ID for block 154₃. In this regard, note that given that block 154₃ includes two RXs, the request from PM 154₃ may comprise one request identifying both or one RX, or two different requests each identifying an RX. In this regard, block 154₃ may correspond to two power domains requiring two functions or features to be activated at the same time (e.g., camera and microphone for a video call). As such, the message from transmit module 114 may comprise two messages 200—one for RX 158₃₁ and another for RX 158₃₂. Upon receipt of their respective Repair_ID and Repair_Data or repair signature, RX 158₃₁ and 158₃₂ may independently conduct memory repair.

In accordance with an aspect of the disclosed technology, the repair data is stored in OTP controller 118 based on RX_ID. This alleviates the need to store the repair data in the OTP in a particular order, e.g., block/subsystem 1, block/subsystem 2, block/subsystem 3, etc. In accordance with the disclosed technology, repair data can be stored randomly in any order. It also allows for allocation of the memory dependent on how many memory elements associated with a given memory device require repair. Thus, the OTP memory can be allocated based on what and how many memory elements are actually failing for a given device or chip. As such, fixed memory need not be allocated in the OPTP memory for each device or chip in the system.

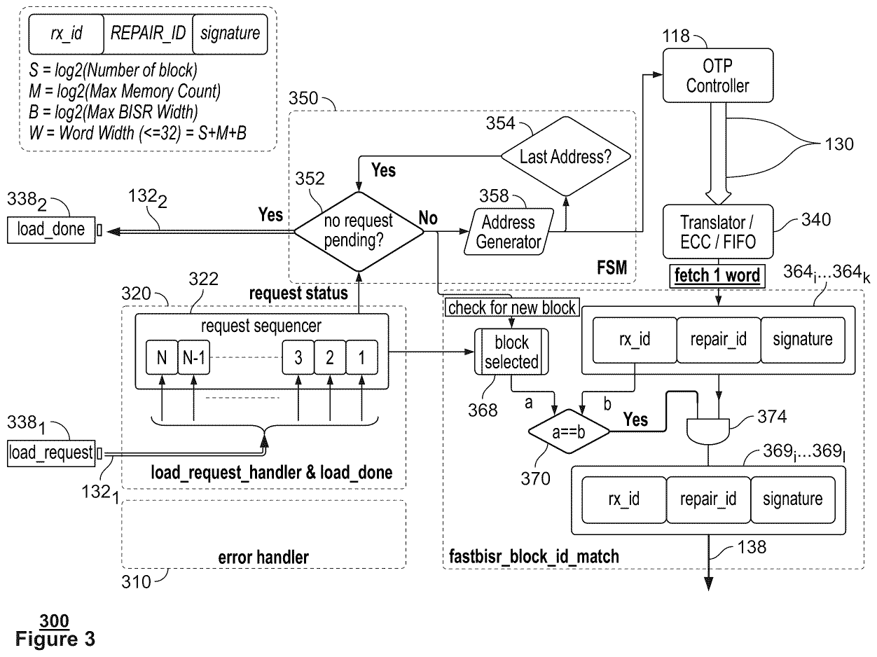

FIG. 3 depicts an example of a high level block diagram and associated process or logic flow for a transmit module 300 in accordance with an aspect of the disclosed technology. Transmit module 138 may be implemented using the layout and logic flow of transmit module 300. As shown, transmit module 300 includes error handler 310, load handler 320, translator/ECC/FIFO block 340, finite state machine (FSM) block 350 and output block 360. Error handler 310 includes error handling logic to take care of internal error conditions that may occur within transmit module 300. Error handler 320 may, for example, communicate with the system/software and provide interrupts.

Load handler 320 receives load requests 338₁ from the power managers (PMs) associated with different power domains via data bus line 132₁. The load requests are sampled by and stored in request sequencer 322 for a predetermined time period. The time period allows the request sequencer to gather requests for multiple power domains so that multiple requests can be processed each time the repair data is read from the OTP controller 118. Once the predetermined time period expires, the entire contents of the OTP memory is read and the requests accumulated during the predetermined time period are processed. The predetermined time period may be based on the latency number of the SoC that includes a system 100 in accordance with an aspect of the disclosed technology.

As shown, the request sequencer 322 may store N requests associated with various power managers or power domains. In accordance with an aspect of the disclosed technology, each request associated with a power domain may be identified by an index value (e.g., 1 through N) or using the RX_ID discussed above. In some examples, the index value may be different than the RX_ID, while in other examples it may comprise the RX_ID.

The request status condition is determined at decision diamond 352. If no request is pending (output=Yes at decision diamond 352) and the last address associated with the requests in the sequencer (e.g., request n) has been generated as shown via decision diamond 354, then a load complete or done message 338₂ is provided via data bus 132₂ to the PMs 126/154. Last address decision diamond 354 provides an output of Yes when the last address in the current request sequence is reached as indicated that the current work flow associated with the sequencer is completed. In effect, the flow goes from 354 to 352 and then Yes 132 and issues a load done 3382.

If one or more requests are pending (output =No at decision diamond 352), then address generator 358 is used to generate the RX_ID associated with the index value stored with the request in the request sequencer 322. As shown, the address generator 358 is also coupled to the OTP controller 118 and provides the RX_ID(s) to the OTP controller 118. The RX_ID(s) are then used to output OTP memory data, e.g., read data buffered in the OTP controller, to the translator/ECC/FIFO block 340 via bus 130. In addition, if one or more requests are pending at the end of the predetermined time period, the OTP controller 118 is prompted to output the entire contents of the OTP memory via bus 130. Specifically, the OTP controller 118 may be prompted via data bus 130 in FIG. 1 (though that detail is not explicitly shown in FIG. 2) resulting in a read out of the entire contents of OTP memory via bus 130. Further, address generator 358 operates to generate RX_ID addresses for each pending request if no request is not pending (output=No at decision diamond 352).

Translator/ECC/FIFO block 340 processes the entire contents of the OTP memory it receives on bus 130. For instance, translator/ECC/FIFO block 340 uses the address(es) to locate the repair word. The repair ID and repair signature, along with the RX_ID are used to prepare messages(s) 364. Each message is sent out provided the request block selector indicator 368 includes a request that corresponds to a RX_ID of a message 364. As shown in FIG. 3, this functionality is implemented via decision diamond 370 and logic gate 374. In operation, the request sequencer 322 provides each request block (i.e., requests 1 through N) to block selector indicator 368 and a comparison made to determine that each message 364 is associated with a block selected from request sequencer 322. If there is a match, then a message 369 is broadcasted on repair network 138 where it is detected and decoded by the appropriate RX unit, e.g., the RX unit associated with the RX_ID in the message 369. In this regard, we note that different messages 369 sent over time would correspond to different RX_ID corresponding to all the requests that were existing.

As part of its processing, translator/ECC/FIFO block 340 includes a translator logic that translates the contents it receives from the OTP memory into messages 364. Block 340 may also perform ECC on the data retrieved from the OTP memory and include an ECC with message 364. This processing is optional as there is no need to use ECC in accordance with the disclosed technology. The FIFO buffer in translator block 340 need only be large enough to store one word. In this regard, the OTP memory (fuse) may be sized to accommodate 8192 bits. For a repair word, such as for example repair word 200 of FIG. 2, of length 26 bits, it is possible to store 8192/26 or 315 words in the OTP memory. The OTP controller 118 may fetch and store data in the FIFO translator 340 at 32 bits at a time. In a case where the translator block 340 transfers 32 can store 128 bits of data, the translator can have 4 complete words at a point in time. The fetch_1_word fetches one complete word at a time.

As indicated, the configuration and operation shown via FIG. 3 is capable of processing multiple requests in parallel. In particular, requests are in effect batched in the request sequencer 322 periodically. When the period expires, the contents of the OTP memory are processed for each batched request and broadcasted in one or more messages on the repair data bus. This approach is more efficient than conventional approaches in that the time it takes to process the requests is effectively bounded by the time it takes to read the contents of the OTP memory. If additional requests are received while the current requests are being processed, the current repair cycle or window of repair is completed by processing the current requests. In this regard, the request sequencer keeps the additional requests pending until the current requests are processed. Once the current requests are processed, it then processes the additional requests that are pending.

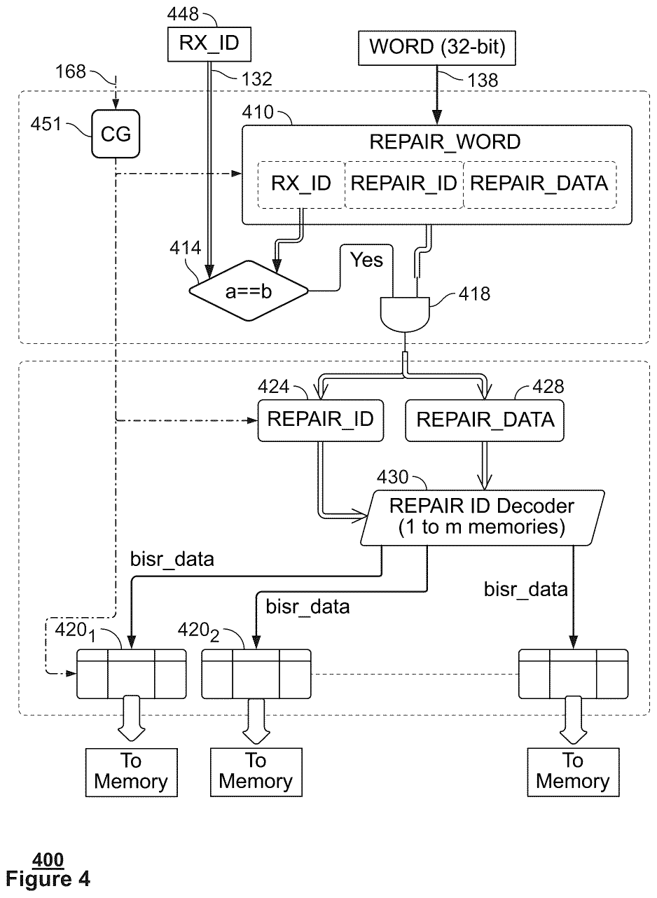

FIG. 4 is a diagram illustrating a receive (RX) unit 400 and associated processing flow in accordance with an aspect of the disclosed technology. The RX unit 400 receive repair data via repair bus 138 in the form of a repair message or word 410 from transmit module 114. It also receives a clock signal 168 from transmit module 114. A repair message or word 410 is received in each clock cycle. The clock signal 168 is used in processing the repair message 410 to time how data is read out some of the elements (e.g., 410, 424, 428, 420) included in RX unit 400. As shown, the repair message 410 is initially processed to determine that it includes repair data for RX unit 400. Specifically, the RX ID in the message is compared to a RX ID 448 received via bus 132 as shown at decision diamond 414. If there is a match as a result of this comparison, the logic gate 418 outputs the repair ID 424 and repair data 428 to ID decoder 430. ID decoder processes the repair ID 424 so as to provide the repair data 428 to the appropriate memory elements 420. If there is no match as a result of the comparison, then no data is included in the repair word 410 and the repair word is not further processed.

RX unit 400 includes as an additional element clock gate (CG) 451. CG 451 receives a clock signal 168 from transmit module 114. The CG 451 is controlled by the power manager associated with RX unit 500 and used to reduce the power consumption by the unit. In effect, CG 451 removes the clock signal from the elements of the RX unit 500 thereby disabling the unit. For instance, in periods where a given power domain is inactive, the power manager may enable the clock gate so that the corresponding RX unit does not consume power.

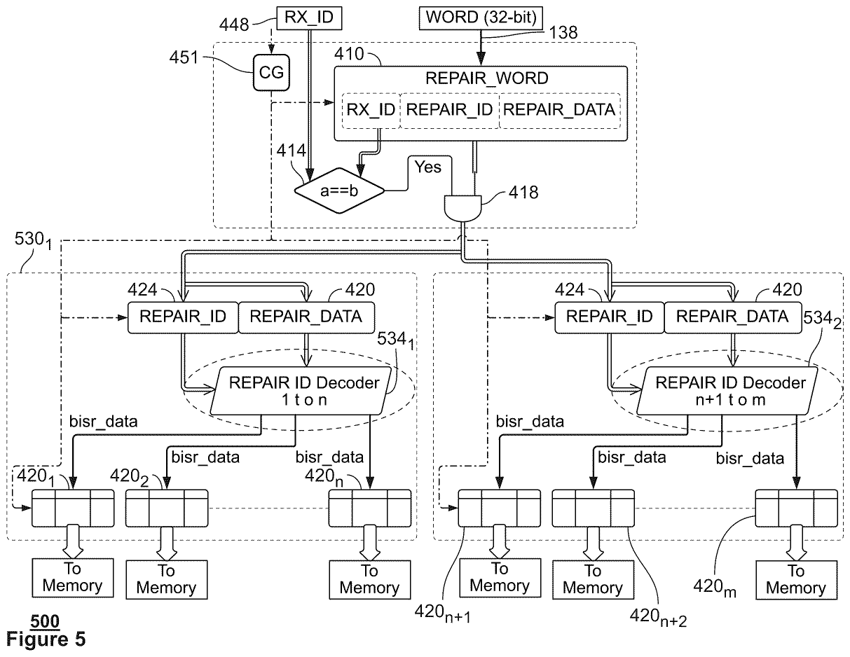

FIG. 5 is a diagram illustrating a receive (RX) unit 600 and associated processing flow in accordance with an aspect of the disclosed technology. Elements in RX unit 500 that are similar to those in RX units 400 are labelled with the same reference numbers as in FIG. 4. RX unit 500 is configured to address situations involving large memories. Specifically, the repair ID decoder functionality is split between two decoding modules 530 where the number of memory elements m is large. As shown, decoding module 5301 is configured to process repair data for memory elements 1 through n, while decoding module 5302 is configured to process repair data for memory elements n+1 through m. In contrast, in FIG. 4, a single decoding module 430 is configured to process repair data for all memories. Splitting the decoding module functionality among multiple modules allows for reduction in congestion. More generally, it allows for a modular structure that can be used to reduce the size of the decoder 534.

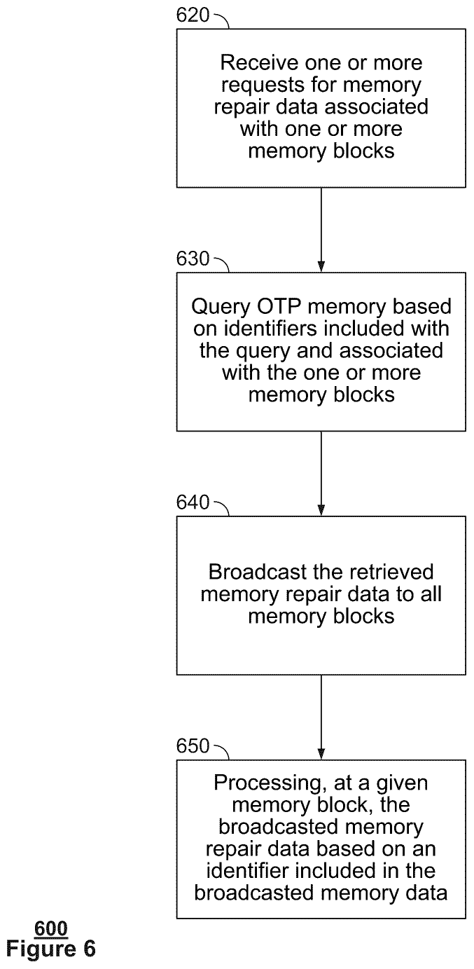

FIG. 6 illustratively depicts a high level processing flow 600 in accordance with an aspect of the disclosed technology. The process flow 600 may be performed by a memory controller such as those discussed in accordance with the previous drawings. As shown at block 620, the process begins upon receipt of one or more requests for memory repair data associated with one or more memory blocks of a computing device, such as, for example, a cellular telephone, laptop, tablet, or, in general, any device that makes use of a processor. Typically, requests are initiated by power managers associated with memory blocks. Requests include identifiers that identify the memory block from which the request originated and signals to a memory controller or transmit module, in accordance with the foregoing disclosure, that a memory block is moving to an active state and requires its memory repair data. The identifiers may comprise RX_IDs as discussed above.

The memory controller or transmit module processes requests by querying the OTP memory (e.g., fuse box) for the requested repair data as shown at block 630. The request may be provided to an OTP controller which then queries the OTP memory or, alternatively, the memory controller or transmit module may access the OTP memory without using an OTP controller. For example, the OTP controller functionality may be implemented in the transmit module. The query will return contents of the OTP memory associated with the relevant receiver identifiers.

At block 640, the results of the query, i.e., memory repair data, are broadcasted to all memory blocks in the system. The memory repair data that is broadcasted includes receiver identifiers that associates memory repair data with respective memory blocks. At block 650, memory repair data intended for a given memory block is processed only at that block, while memory blocks for which memory repair data is not intended does not process the memory repair data broadcasted to the memory blocks. In this regard, because the memory repair data includes receiver or memory block identifiers, if a memory block does not detect its receiver or memory block identifier in the memory repair data, it does not process the memory repair data. In some examples, memory blocks for which their respective power managers did not request memory repair data may be kept inactive during processing of requests by other power managers and therefore not process the broadcast memory repair data by virtue of their inactive state.

The disclosed technology may take the form of a system, process or method, or an apparatus. Examples of such systems, process or method, or apparatus may include combinations of one or more of the following features listed below:
F1. A memory repair system, comprising:
   a memory repair controller having a transmit unit and a one time programming memory controller;
   a plurality of memory blocks, each memory block having a receive unit and a power manager; and
   one or more parallel data buses communicatively coupled between the transmit unit of the memory repair controller and at least one receive unit of the plurality of memory blocks and communicatively coupled between the transmit unit of the memory repair controller and at least one power manager of the plurality of memory blocks.
F2. The memory repair system of F1, wherein the at least one power manager requests memory repair data from the transmit unit of the memory repair controller.
F3. The memory repair system of any one of F1 to F2, wherein the at least one power manager requests memory repair data using a request that includes a receive unit identifier and a repair identifier associated with the at least one receive unit.
F4. The memory repair system of any one of F1 to F3, wherein the transmit unit transmits repair data to the at least one receive unit using the receive unit identifier.
F5. The memory repair system of any one of F1 to F4, wherein the repair data includes a repair signature for the at least one receive unit.
F6. The memory repair system of any one of F1 to F5, wherein the receive unit identifier identifies a specific memory within a memory block associated with the at least one power manager.
F7. The memory repair system of any one of F1 to F6, wherein a first data bus of the plurality of parallel data buses is used from transmitting data from the transmit unit of the memory repair controller to the at least one receive unit of the plurality.
F8. The memory repair system of any one of F1 to F7, wherein a second data bus of the plurality of parallel data buses is used for transmitting data between the transmit unit and the at least one power manager of the plurality of memory blocks.
F9. The memory repair system of any one of F1 to F8, wherein the first data bus is different than the second data bus.
F10. The memory repair system of any one of F1 to F9, wherein the one or more parallel data buses include a parallel repair bus for communicating repair data from the transmit unit of the memory repair controller to a receive unit of each of the plurality of memory blocks.
F11. The memory repair system of any one of F1 to F10, wherein the one or more parallel data buses includes a parallel request bus for communicating repair requests between a power manager of each of the plurality of memory blocks and the transmit unit.
F12. The memory repair system of any one of F1 to F11, wherein each memory block of the plurality of memory blocks is associated with a power domain of a system on a chip.
F13. The memory repair system of any one of F1 to F12, wherein the one or more parallel data buses comprise one or more parallel broadcast buses.
F14. The memory repair system of any one of F1 to F13, wherein the transmit unit comprises a request sequencer receiving memory repair requests from at least one power manager.
F15. A memory repair controller, comprising:
   a load request handler having a request sequencer and configured to receive memory repair requests from one or more power managers;
   a translator coupled to a one time programmable memory and configured to receive repair data stored in the one time programmable memory;
   a logic for comparing receiver identifiers associated with the one or more power managers to the received memory repair requests to determine whether a given part of the memory repair data received by the translator corresponds to a memory repair request; and
   an output that broadcasts a message to one or more receive units when the logic indicates that there is a match between a receiver identifier and a memory repair request of the received memory requests.
F16. The memory repair controller of any one of F1 to F15, wherein the request sequencer accumulates received memory requests for a predetermined time period.
F17. The memory repair controller of any one of F1 to F16, wherein the memory repair controller causes the one time programmable memory to provide its contents to the translator after the predetermined time period expires.
F18. The memory repair controller of any one of F1 to F15, wherein the logic receives memory repair requests from the request sequencer.
F19. A memory repair system of any of F1 to F18.
F20. A method for performing memory repair, comprising:
   receiving, at a memory repair controller, a request for repair data associated with a memory block;
   receiving, at the memory repair controller, memory repair data associated with the memory block;
   broadcasting, by the memory repair controller, the memory repair data on a parallel broadcast data bus coupled to the memory block and at least one other memory block;
   receiving at the memory block the repair data; and
   processing one or more memories associated with the memory block based on the memory repair data.
F21. The method of F20, wherein broadcasting the memory repair data comprises broadcasting the memory data and receive unit identifier associated with a receive unit of the memory block.
F22. The method of any one of F20 to F21, comprising sending, by a power manager of the memory block, the request for repair data on a repair data bus.
F23. The method of any one of F20 to F22, wherein the repair data is contained in a repair word and processing comprises determining a receive unit identifier associated with the repair word and decoding a repair signature from the repair word when the receive unit identifier is determined to match an identifier associated with the memory block.
F24. The method of any one of F20 to F23, wherein the method is performed using the system of any of F15 to F18.
F25. The method of any one of F20 to F23, wherein the method is performed using the memory repair controller of any of F1 to F14.

Although the technology herein has been described with reference to particular examples, it is to be understood that these examples are merely illustrative of the principles and applications of the disclosed technology. It is, therefore, to be understood that numerous modifications may be made to the illustrative examples and that other arrangements may be devised without departing from the spirit and scope of the present technology as defined by the appended claims.

Unless otherwise stated, the foregoing alternative examples are not mutually exclusive, but may be implemented in various combinations to achieve unique advantages. As these and other variations and combinations of the features discussed above can be utilized without departing from the subject matter defined by the claims, the foregoing description should be taken by way of illustration rather than by way of limitation of the subject matter defined by the claims. In addition, the provision of the examples described herein, as well as clauses phrased as “such as,” “including,” and the like, should not be interpreted as limiting the subject matter of the claims to the specific examples; rather, the examples are intended to illustrate only some but not all possible variations of the disclosed technology. Further, the same reference numbers in different drawings can identify the same or similar elements.

1. A memory repair system, comprising:
a memory repair controller having a transmit unit and a one time programming memory controller;
a plurality of memory blocks, each memory block having a receive unit and a power manager; and
one or more parallel data buses communicatively coupled between the transmit unit of the memory repair controller and at least one receive unit of the plurality of memory blocks and communicatively coupled between the transmit unit of the memory repair controller and at least one power manager of the plurality of memory blocks.

2. The memory repair system of claim 1, wherein the at least one power manager requests memory repair data from the transmit unit of the memory repair controller.

3. The memory repair system of claim 2, wherein the at least one power manager requests memory repair data using a request that includes a receive unit identifier and a repair identifier associated with the at least one receive unit.

4. The memory repair system of claim 3, wherein the transmit unit transmits repair data to the at least one receive unit using the receive unit identifier.

5. The memory repair system of claim 4, wherein the repair data includes a repair signature for the at least one receive unit.

6. The memory repair system of claim 5, wherein the receive unit identifier identifies a specific memory within a memory block associated with the at least one power manager.

7. The memory repair system of claim 1, wherein a first data bus of the plurality of parallel data buses is used from transmitting data from the transmit unit of the memory repair controller to the at least one receive unit of the plurality.

8. The memory repair system of claim 7, wherein a second data bus of the plurality of parallel data buses is used for transmitting data between the transmit unit and the at least one power manager of the plurality of memory blocks.

9. The memory repair system of claim 8, wherein the first data bus is different than the second data bus.

10. The memory repair system of claim 1, wherein the one or more parallel data buses include a parallel repair bus for communicating repair data from the transmit unit of the memory repair controller to a receive unit of each of the plurality of memory blocks.

11. The memory repair system of claim 1, wherein the one or more parallel data buses includes a parallel request bus for communicating repair requests between a power manager of each of the plurality of memory blocks and the transmit unit.

12. The memory repair system of claim 1, wherein each memory block of the plurality of memory blocks is associated with a power domain of a system on a chip.

13. The memory repair system of claim 1, wherein the one or more parallel data buses comprise one or more parallel broadcast buses.

14. The memory repair system of claim 1, wherein the transmit unit comprises a request sequencer receiving memory repair requests from at least one power manager.

15. A method for performing memory repair, comprising:
receiving, at a memory repair controller, a request for repair data associated with a memory block;
receiving, at the memory repair controller, memory repair data associated with the memory block;
broadcasting, by the memory repair controller, the memory repair data on a parallel broadcast data bus coupled to the memory block and at least one other memory block;
receiving at the memory block the repair data; and
processing one or more memories associated with the memory block based on the memory repair data.

16. The method of claim 15, wherein broadcasting the memory repair data comprises broadcasting the memory data and receive unit identifier associated with a receive unit of the memory block.

17. The method of claim 15, comprising sending, by a power manager of the memory block, the request for repair data on a repair data bus.

18. The method of claim 15, wherein the repair data is contained in a repair word and processing comprises determining a receive unit identifier associated with the repair word and decoding a repair signature from the repair word when the receive unit identifier is determined to match an identifier associated with the memory block.

19. A memory repair controller, comprising:
a load request handler having a request sequencer and configured to receive memory repair requests from one or more power managers;
a translator coupled to a one time programmable memory and configured to receive repair data stored in the one time programmable memory;
a logic for comparing receiver identifiers associated with the one or more power managers to the received memory repair requests to determine whether a given part of the memory repair data received by the translator corresponds to a memory repair request; and
an output that broadcasts a message to one or more receive units when the logic indicates that there is a match between a receiver identifier and a memory repair request of the received memory requests.

20. The memory repair controller of claim 19, wherein the request sequencer accumulates received memory requests for a predetermined time period.

21. The memory repair controller of claim 20, wherein the memory repair controller causes the one time programmable memory to provide its contents to the translator after the predetermined time period expires.

22. The memory repair controller of claim 19, wherein the logic receives memory repair requests from the request sequencer.
